(19) United States
(12) Patent Application Publication
(10) Pub. No.: US 2026/0079406 A1
(43) Pub. Date: Mar. 19, 2026

(54) METHOD AND APPARATUS FOR CONTROLLING A LITHOGRAPHIC APPARATUS, AND A LITHOGRAPHIC APPARATUS

(71) Applicant: ASML NETHERLANDS B.V., Veldhoven (NL)

(72) Inventor: Wenjie JIN, Eindhoven (NL)

(73) Assignee: ASML NETHERLANDS B.V., Veldhoven (NL)

(21) Appl. No.: 19/109,110

(22) PCT Filed: Sep. 6, 2023
(86) PCT No.: PCT/EP2023/074387

§ 371 Date: Mar. 5, 2025

(30) Foreign Application Priority Data
Oct. 6, 2022 (EP) 22199967.5

(51) Int. Cl. G03F 7/00

(52) U.S. Cl. CPC G03F 7/70504; G03F 7/70158; G03F 7/70891

(57) ABSTRACT

A computer-implemented method of generating one or more control actions for controlling a lithographic apparatus. The lithographic apparatus comprises an illumination system for illuminating a mask with a non-uniform radiation beam. The illumination system is configured to receive from a radiation source a radiation beam, and comprising a beam-shaping device configured to receive data specifying profile information, and shape a transverse profile of the radiation beam based on the profile information to form the non-uniform radiation beam. The method comprises processing the profile information to generate an estimated diffraction pattern produced by illuminating the mask with the non-uniform radiation beam, and processing the estimated diffraction pattern to generate one or more control actions for a control system of the lithographic apparatus.

### CROSS-REFERENCE TO RELATED APPLICATIONS

This application claims priority of EP Application Serial No. 22199967.5 which was filed on Oct. 6, 2022 and which is incorporated herein in its entirety by reference.

### FIELD

The present invention relates to a method and apparatus for controlling a lithographic apparatus, and to a lithographic apparatus.

### BACKGROUND

A lithographic apparatus is a machine constructed to apply a desired pattern onto a substrate. A lithographic apparatus can be used, for example, in the manufacture of integrated circuits (ICs). A lithographic apparatus may, for example, project a pattern (also often referred to as “design layout” or “design”) at a patterning device (e.g., a mask) onto a layer of radiation-sensitive material (resist) provided on a substrate (e.g., a wafer).

To project a pattern on a substrate a lithographic apparatus may use electromagnetic radiation. The wavelength of this radiation determines the minimum size of features which can be formed on the substrate. Typical wavelengths currently in use are 365 nm (i-line), 248 nm, 193 nm and 13.5 nm. A lithographic apparatus, which uses extreme ultraviolet (EUV) radiation, having a wavelength within the range 4-20 nm, for example 6.7 nm or 13.5 nm, may be used to form smaller features on a substrate than a lithographic apparatus which uses, for example, radiation with a wavelength of 193 nm.

Low-k₁ lithography may be used to process features with dimensions smaller than the classical resolution limit of a lithographic apparatus. In such process, the resolution formula may be expressed as CD=k₁×λ/NA, where λ is the wavelength of radiation employed, NA is the numerical aperture of the projection optics in the lithographic apparatus, CD is the “critical dimension” (generally the smallest feature size printed, but in this case half-pitch) and k₁ is an empirical resolution factor. In general, the smaller k₁ the more difficult it becomes to reproduce the pattern on the substrate that resembles the shape and dimensions planned by a circuit designer in order to achieve particular electrical functionality and performance. To overcome these difficulties, sophisticated fine-tuning steps may be applied to the lithographic projection apparatus and/or design layout. These include, for example, but not limited to, optimization of NA, customized illumination schemes, use of phase shifting patterning devices, various optimization of the design layout such as optical proximity correction (OPC, sometimes also referred to as “optical and process correction”) in the design layout, or other methods generally defined as “resolution enhancement techniques” (RET). Alternatively, tight control loops for controlling a stability of the lithographic apparatus may be used to improve reproduction of the pattern at low k1.

It is frequently difficult to maintain a lithographic apparatus at its optimum operating conditions. For example, electromagnetic radiation incident on optical surfaces within the lithographic apparatus (e.g. a surface of a mirror or a lens) may cause thermal aberration of those optical surfaces, reducing the performance of the lithographic apparatus. Thermal aberration of this kind may be compensated for by selective heating and/or cooling of the optical surfaces.

This can be done, for example, by using a mathematical model to first predict wave front errors caused by the thermal aberrations and then derive control actions, such as heating and/or cooling of the optical surfaces, to reduce the wave front errors. To predict the wave front errors accurately, the model takes the spatial distribution of the electromagnetic radiation incident on the optical surfaces as input, and considers the underlying physics of each component of the lithographic apparatus.

For example, the spatial distribution of electromagnetic radiation on a mirror that reflects an optical image from a mask is generally determined by the diffraction pattern of the mask. Conventionally, knowledge of the mask is needed to derive the corresponding diffraction pattern, and to perform thermal compensation using the aforementioned mathematical model. Details of the mask—and the corresponding diffraction pattern—are, however, often proprietary to the user and not available to the control system of the lithographic apparatus.

It is therefore desirable to provide improved control systems which are capable of compensating for thermal aberration, or reducing thermal aberration, without requiring detailed knowledge of the mask.

### SUMMARY

It is an object of the present invention to provide new and useful methods and systems for improved control of a lithographic apparatus.

A first aspect of the invention proposes a computer-implemented method of generating one or more control actions for controlling a lithographic apparatus. The lithographic apparatus comprises an illumination system for illuminating a mask with a non-uniform radiation beam. The illumination system is configured to receive from a radiation source a radiation beam, and comprises a beam-shaping device configured to receive data specifying profile information, and shape a profile of the radiation beam based on the profile information to form the non-uniform radiation beam. The method comprises processing the profile information to generate an estimated diffraction pattern produced by illuminating the mask with the non-uniform radiation beam, and

processing the estimated diffraction pattern to generate one or more control actions for a control system of the lithographic apparatus.

The method enables more accurate control of the lithographic apparatus, particularly when the computer which generates the control actions has no access to the details of the mask, such as whether the mask is a line or hole pattern or the like. However, since the profile information was typically selected by an individual (or computer system) based on knowledge of the mask, it is informative to some degree about the mask, and thus informative about the diffraction pattern which the mask produces.

For example, the profile information may have been generated by source mask optimization or source only optimization. Optionally, the method may comprise a step of generating the profile information by a source mask optimization or source only optimization based on a mask pattern.

Optionally, processing the profile information to generate an estimated diffraction pattern produced by the illumination system may comprise processing the profile information to generate a candidate mask pattern, processing the candidate mask pattern to generate a candidate diffraction pattern, and processing the candidate diffraction pattern and the profile information to generate the estimated diffraction pattern produced by the illumination system. For example, the estimated diffraction pattern may be computer-generated as a diffraction pattern which the mask would produce if it were substantially identical to the candidate diffraction pattern.

Optionally, processing the profile information to generate a candidate mask pattern may comprise processing the profile information using a clustering algorithm to generate clustering information, and processing the clustering information to generate the candidate mask pattern. The clustering information may include a total number of clusters identified by the clustering algorithm, and shape information and position information for each identified cluster. This improves the method as it enables reliable extraction of the major features included in the profile information while it filters out minor features which do need to be considered for generating effective control actions.

Optionally, processing the clustering information to generate the candidate mask pattern may comprise processing the clustering information to determine, as a determination result, whether the candidate mask pattern is a line pattern or a hole pattern, processing the shape information and the position information for each identified cluster to determine a pitch of the candidate mask pattern, and processing the determination result and the pitch of the estimated mask to generate the candidate mask pattern.

When processing the profile information to generate an estimated diffraction pattern produced by the illumination system comprises processing the candidate diffraction pattern and the profile information to generate the estimated diffraction pattern produced by the illumination system, processing the candidate diffraction pattern and the profile information may comprise performing a convolution of the candidate diffraction pattern and the profile information to generate the estimated diffraction pattern.

Optionally, the beam-shaping device may comprise a programmable mirror array.

When the beam-shaping device comprises a programmable mirror array, the profile information may be a two-dimensional array specifying a configuration of the programmable mirror array.

Optionally, the control system may be configured to apply a thermal conditioning process (e.g. a heating process in selected location(s), and/or a cooling process, such as water cooling, in selected location(s)) based on the control actions to of at least part of the lithographic apparatus.

When the control system is configured to apply a thermal conditioning process based on the control actions to of at least part of the lithographic apparatus, the control system may be configured to apply the thermal conditioning process an optical element of the lithographic apparatus (such as a mirror surface of a mirror, or a surface of a lens). The optical element may include an optical surface including a plurality of regions, and the one or more control actions control the control system to apply a respective selected thermal conditioning process to each of the regions of the optical surface. In this case, the optical element may be a mirror. Thus, the respective thermal condition process for each of the regions of the optical surface may be selected individually (e.g. subject to any overall constraints on the set of selected thermal conditioning processes), and may differ for different ones of the regions.

Note however, that instead of, or in addition to, a thermal conditioning process, the control actions may effect mirror micro-adjustments, e.g. using actuator controlled by the control system, such as applying a selected amount of force to the optical element of the lithographic apparatus (e.g. in selected locations on the optical element) to cause it to flex.

A second aspect of the invention proposes a computer system comprising a processor and a data storage device, the data storage device storing program instructions which, when executed by the processor, cause the processor to carry out a method according to the first aspect of the invention.

A third aspect of the invention proposes a computer program product comprising instructions which, when executed by a computer, cause the computer to carry out a method according to the first aspect of the invention. The computer program product may be a computer-readable storage medium such as a tangible storage device, or it may be software downloadable over a data transmission system, such as the internet.

A fourth aspect of the invention proposes a control apparatus for a lithographic apparatus. The lithographic apparatus comprises an illumination system for illuminating a mask with a non-uniform radiation beam. The illumination system is configured to receive from a radiation source a radiation beam, and comprises a beam-shaping device configured to receive data specifying profile information, and shape a profile of the radiation beam based on the profile information to form the non-uniform radiation beam. The control apparatus is configured to process the profile information to generate an estimated diffraction pattern produced by illuminating the mask with the non-uniform radiation beam, and process the estimated diffraction pattern to generate one or more control actions for a control system of the lithographic apparatus.

Features of the control apparatus, the lithographic apparatus and the illumination system may be as explained above in relation to the first aspect of the invention.

### BRIEF DESCRIPTION OF THE DRAWINGS

Embodiments of the invention will now be described, by way of example only, with reference to the accompanying schematic drawings, in which:

FIG. 1 depicts a schematic overview of a lithographic apparatus;

FIG. 2 depicts a schematic overview of a lithographic cell;

FIG. 3 depicts a schematic representation of holistic lithography, representing a cooperation between three key technologies to optimize semiconductor manufacturing;

FIG. 4 depicts in the top row six examples of profile information, and in the lower row clusters of high intensity points identified in the corresponding profile information;

FIG. 5 is a flow diagram of an example method of generating control actions for controlling the lithographic apparatus;

FIG. 6 is a flow diagram of an example method of processing profile information in a step of the method of FIG. 5;

FIG. 7 is a schematic illustrating the method of FIG. 6;

FIG. 8 shows experimental data obtained by using the method of FIG. 6, and

FIG. 9 shows, for 8 masks, an estimated diffraction pattern generated by using the method of FIG. 6 together with a corresponding simulated diffraction pattern.

### DETAILED DESCRIPTION

In the present document, the terms “radiation” and “beam” are used to encompass all types of electromagnetic radiation, including ultraviolet radiation (e.g. with a wavelength of 365, 248, 193, 157 or 126 nm) and EUV (extreme ultra-violet radiation, e.g. having a wavelength in the range of about 5-100 nm).

The term “reticle”, “mask” or “patterning device” as employed in this text may be broadly interpreted as referring to a generic patterning device that can be used to endow an incoming radiation beam with a patterned cross-section, corresponding to a pattern that is to be created in a target portion of the substrate. The term “light valve” can also be used in this context. Besides the classic mask (transmissive or reflective, binary, phase-shifting, hybrid, etc.), examples of other such patterning devices include a programmable mirror array and a programmable LCD array.

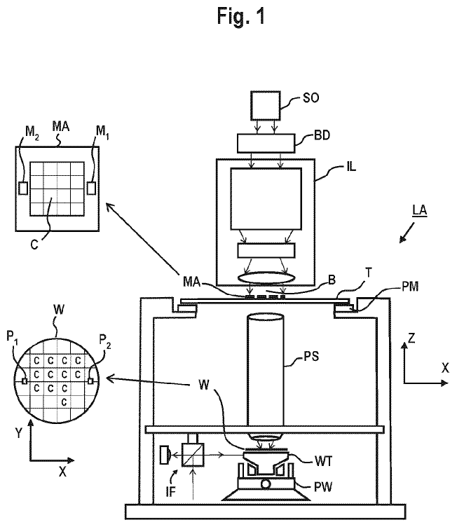

FIG. 1 schematically depicts a lithographic apparatus LA. The lithographic apparatus LA includes an illumination system (also referred to as illuminator) IL configured to condition a radiation beam B (e.g., UV radiation, DUV radiation or EUV radiation), a mask support (e.g., a mask table) MT constructed to support a patterning device (e.g., a mask) MA and connected to a first positioner PM configured to accurately position the patterning device MA in accordance with certain parameters, a substrate support (e.g., a wafer table) WT constructed to hold a substrate (e.g., a resist coated wafer) W and connected to a second positioner PW configured to accurately position the substrate support in accordance with certain parameters, and a projection system (e.g., a refractive projection lens system) PS configured to project a pattern imparted to the radiation beam B by patterning device MA onto a target portion C (e.g., comprising one or more dies) of the substrate W.

In operation, the illumination system IL receives a radiation beam from a radiation source SO, e.g. via a beam delivery system BD. The illumination system IL may include various types of optical components, such as refractive, reflective, magnetic, electromagnetic, electrostatic, and/or other types of optical components, or any combination thereof, for directing, shaping, and/or controlling radiation. The illuminator IL may be used to condition the radiation beam B to have a desired spatial and angular intensity distribution in its cross section at a plane of the patterning device MA.

The term “projection system” PS used herein should be broadly interpreted as encompassing various types of projection system, including refractive, reflective, catadioptric, anamorphic, magnetic, electromagnetic and/or electrostatic optical systems, or any combination thereof, as appropriate for the exposure radiation being used, and/or for other factors such as the use of an immersion liquid or the use of a vacuum. Any use of the term “projection lens” herein may be considered as synonymous with the more general term “projection system” PS.

The lithographic apparatus LA may be of a type wherein at least a portion of the substrate may be covered by a liquid having a relatively high refractive index, e.g., water, so as to fill a space between the projection system PS and the substrate W-which is also referred to as immersion lithography. More information on immersion techniques is given in U.S. Pat. No. 6,952,253, which is incorporated herein by reference.

The lithographic apparatus LA may also be of a type having two or more substrate supports WT (also named “dual stage”). In such “multiple stage” machine, the substrate supports WT may be used in parallel, and/or steps in preparation of a subsequent exposure of the substrate W may be carried out on the substrate W located on one of the substrate support WT while another substrate W on the other substrate support WT is being used for exposing a pattern on the other substrate W.

In addition to the substrate support WT, the lithographic apparatus LA may comprise a measurement stage. The measurement stage is arranged to hold a sensor and/or a cleaning device. The sensor may be arranged to measure a property of the projection system PS or a property of the radiation beam B. The measurement stage may hold multiple sensors. The cleaning device may be arranged to clean part of the lithographic apparatus, for example a part of the projection system PS or a part of a system that provides the immersion liquid. The measurement stage may move beneath the projection system PS when the substrate support WT is away from the projection system PS.

In operation, the radiation beam B is incident on the patterning device, e.g. mask, MA which is held on the mask support MT, and is patterned by the pattern (design layout) present on patterning device MA. Having traversed the mask MA, the radiation beam B passes through the projection system PS, which focuses the beam onto a target portion C of the substrate W. With the aid of the second positioner PW and a position measurement system IF, the substrate support WT can be moved accurately, e.g., so as to position different target portions C in the path of the radiation beam B at a focused and aligned position. Similarly, the first positioner PM and possibly another position sensor (which is not explicitly depicted in FIG. 1) may be used to accurately position the patterning device MA with respect to the path of the radiation beam B. Patterning device MA and substrate W may be aligned using mask alignment marks M1, M2 and substrate alignment marks P1, P2. Although the substrate alignment marks P1, P2 as illustrated occupy dedicated target portions, they may be located in spaces between target portions. Substrate alignment marks P1, P2 are known as scribe-lane alignment marks when these are located between the target portions C.

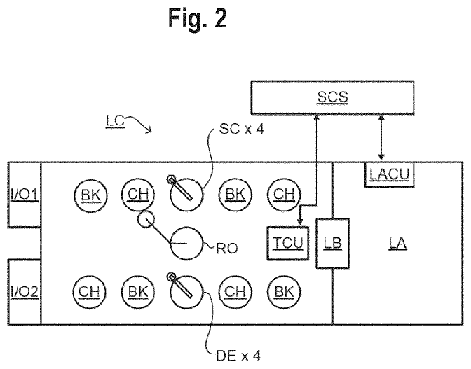

As shown in FIG. 2 the lithographic apparatus LA may form part of a lithographic cell LC, also sometimes referred to as a lithocell or (litho) cluster, which often also includes apparatus to perform pre- and post-exposure processes on a substrate W. Conventionally these include spin coaters SC to deposit resist layers, developers DE to develop exposed resist, chill plates CH and bake plates BK, e.g. for conditioning the temperature of substrates W e.g. for conditioning solvents in the resist layers. A substrate handler, or robot, RO picks up substrates W from input/output ports I/O1, I/O2, moves them between the different process apparatus and delivers the substrates W to the loading bay LB of the lithographic apparatus LA. The devices in the lithocell, which are often also collectively referred to as the track, are typically under the control of a track control unit TCU that in itself may be controlled by a supervisory control system SCS, which may also control the lithographic apparatus LA, e.g. via lithography control unit LACU.

In order for the substrates W exposed by the lithographic apparatus LA to be exposed correctly and consistently, it is desirable to inspect substrates to measure properties of patterned structures, such as overlay errors between subsequent layers, line thicknesses, critical dimensions (CD), etc. For this purpose, inspection tools (not shown) may be included in the lithocell LC. If errors are detected, adjustments, for example, may be made to exposures of subsequent substrates or to other processing steps that are to be performed on the substrates W, especially if the inspection is done before other substrates W of the same batch or lot are still to be exposed or processed.

An inspection apparatus, which may also be referred to as a metrology apparatus, is used to determine properties of the substrates W, and in particular, how properties of different substrates W vary or how properties associated with different layers of the same substrate W vary from layer to layer. The inspection apparatus may alternatively be constructed to identify defects on the substrate W and may, for example, be part of the lithocell LC, or may be integrated into the lithographic apparatus LA, or may even be a stand-alone device. The inspection apparatus may measure the properties on a latent image (image in a resist layer after the exposure), or on a semi-latent image (image in a resist layer after a post-exposure bake step PEB), or on a developed resist image (in which the exposed or unexposed parts of the resist have been removed), or even on an etched image (after a pattern transfer step such as etching).

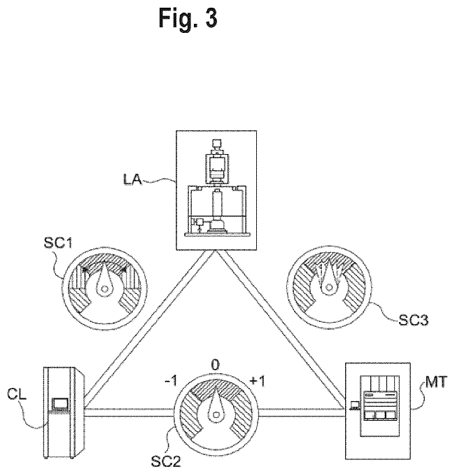

Typically the patterning process in a lithographic apparatus LA is one of the most critical steps in the processing which requires high accuracy of dimensioning and placement of structures on the substrate W. To ensure this high accuracy, three systems may be combined in a so called “holistic” control environment as schematically depicted in FIG. 3. One of these systems is the lithographic apparatus LA which is (virtually) connected to a metrology tool MT (a second system) and to a computer system CL (a third system). The key of such “holistic” environment is to optimize the cooperation between these three systems to enhance the overall process window and provide tight control loops to ensure that the patterning performed by the lithographic apparatus LA stays within a process window. The process window defines a range of process parameters (e.g. dose, focus, overlay) within which a specific manufacturing process yields a defined result (e.g. a functional semiconductor device)—typically within which the process parameters in the lithographic process or patterning process are allowed to vary.

The computer system CL may use (part of) the design layout to be patterned to predict which resolution enhancement techniques to use and to perform computational lithography simulations and calculations to determine which mask layout and lithographic apparatus settings achieve the largest overall process window of the patterning process (depicted in FIG. 3 by the double arrow in the first scale SC1). Typically, the resolution enhancement techniques are arranged to match the patterning possibilities of the lithographic apparatus LA. The computer system CL may also be used to detect where within the process window the lithographic apparatus LA is currently operating (e.g. using input from the metrology tool MT) to predict whether defects may be present due to e.g. sub-optimal processing (depicted in FIG. 3 by the arrow pointing “0” in the second scale SC2).

The metrology tool MT may provide input to the computer system CL to enable accurate simulations and predictions, and may provide feedback to the lithographic apparatus LA to identify possible drifts, e.g. in a calibration status of the lithographic apparatus LA (depicted in FIG. 3 by the multiple arrows in the third scale SC3).

The projection system PS of the lithographic apparatus LA may comprise one or more projection optics boxes (POBs), the projection optics boxes being configured to transmit electromagnetic radiation between the patterning device and the target portion C of the substrate W.

Each of projection optics boxes contains one or more mirrors. The mirror reflects electromagnetic radiation onto a target of the lithographic apparatus, such as a semiconductor wafer. The reflected electromagnetic radiation causes the mirror to deform, resulting in aberration of the mirror and thereby reducing the accuracy of the processing performed by the lithographic apparatus. To compensate for the aberration, each mirror is divided into a plurality of regions. The temperature of each region is controllable by varying the power applied to an auxiliary heating means for each region. Alternatively or additionally, the temperature of each region of the mirror may be controlled by controlling the temperature of a coolant which is used to cool the region of the mirror. In an embodiment, water is used as the coolant, but in variants of the embodiment other coolants may be implemented. If the distribution of heat generation over the mirror(s) is known, then by controlling the temperature of each region of each mirror, any aberration of the mirrors due to the reflected electromagnetic radiation can be compensated for.

In addition to, or instead of, using mirrors, the projection system may be a refractive projection system which employs one or more lens(es), normally multiple lenses. The lenses too are subject to aberrations caused by heating, and a heating and/or cooling system may be employed to manage and reduce these aberrations, by selective heating and/or cooling of different regions of the lenses.

The illuminator IL of the lithographic apparatus LA may comprise a beam-shaping device (not shown) configured to receive data specifying profile information, and to condition the radiation beam B, based on the profile information, to have a desired spatial and angular intensity distribution in its cross section at a plane of the patterning device MA. For this purpose, the illumination system IL may for example arrange for the radiation beam to be reflected successively from a facetted field mirror device and a facetted pupil mirror device. The illumination system IL may include other mirrors or devices in addition to, or instead of, the faceted field mirror device 10 and/or the faceted pupil mirror device.

In general terms, the beam-shaping device is configured to shape the radiation beam B received by the illumination system IL from the radiation source SO, so as to form a non-uniform radiation beam for illuminating the patterning device MA. The term “profile” (or “transverse profile”) is used here to include the radiation intensity of the beam at any given point on the mask, but may also include the angular distribution in the propagation direction of the radiation at each point of the mask, which is not necessarily transverse to the mask. The radiation beam B is shaped based on profile information which may be provided by a user of the lithographic apparatus or which may be derived by a mathematical model or the like. The profile information may specify a configuration of the beam-shaping device (that is, the profile information may be control data for the beam-shaping device, e.g. for the facetted field mirror device and/or faceted pupil mirror device, if these are included in the illuminator IL) which results in the desired spatial and angular intensity distribution of the radiation beam B at a plane of the patterning device MA. Typically, the profile information includes a data array where each element of the array specifies a configuration of an adjustable degree of freedom of the beam-shaping device.

It has been shown that the image fidelity of the pattern projected by the projection system PS onto a target portion C of the substrate W depends on the configuration of the radiation beam illuminating the patterning device MA. In particular, the image fidelity can often be improved by illuminating the patterning device MA with a non-uniform radiation beam. An improved image fidelity may include a reduction of image distortions and/or an improved image resolution. It has further been shown that, to increase the image fidelity, the shape of the radiation beam, i.e. the spatial and angular intensity distribution, needs to be selected based on the patterning device MA, and in particular based on a symmetry of patterning device MA. A user of the lithographic apparatus, knowing the patterning device MA, may therefore configure the radiation beam B by selecting profile information such that the image fidelity of the pattern projected by the projection system PS onto the target portion C of the substrate W is improved.

In an embodiment, a user of the lithographic apparatus may select, from multiple predetermined sets of profile information provided by the lithographic apparatus, profile information that results in the best image fidelity of the pattern projected by the projection system PS onto the target portion C of the substrate W.

In another embodiment, the profile information may be generated as an output of an optimisation process configured to determine a configuration of the beam-shaping device that optimizes the image fidelity of the pattern projected by the projection system PS onto the target portion C of the substrate W, as described in more detail below.

In another embodiment the beam-shaping device is an aperture placed in the beam path of the radiation beam B within the illumination system IL. In this case the profile information may indicate the shape of the aperture.

Optionally, the beam-shaping device may comprise a programmable mirror array (e.g. the facetted field mirror device and/or the faceted pupil mirror device), and the profile information is control data for the programmable mirror array. The programmable mirror array may comprise a plurality of individually controllable mirrors. In this embodiment the radiation beam B may be configured to illuminate the plurality of mirrors. Each of the mirrors may be controlled to be in an on-state or an off-state. A mirror in the on-state may reflect a corresponding part of the incident radiation beam B so as to illuminate the patterning device MA. A mirror in the off-state may prevent a corresponding part of the incident radiation beam B from illuminating the patterning device MA. For example, a mirror in the off-state may be arranged such that the corresponding part of the incident radiation beam B is directed towards a beam block.

When the beam-shaping device comprises a programmable mirror array, the profile information may include a two-dimensional data array specifying a configuration of the programmable mirror array. Each element of the two-dimensional data array may specify whether a corresponding mirror is to be arranged in the on-state or off-state. In other systems, the mirrors may be controlled using other, more sophisticated, control options. For example, the control system may be configured such that each mirror is rotatable by a selected amount about either of two axes, so as to redistribute radiation to another selected portion of the pupil plane, rather than the radiation being wasted.

“Source mask optimization” (SMO) is a known computational method to improve the image fidelity of lithography systems. SMO aims to optimize the image fidelity of the projected pattern by joint optimization of degrees of freedom of the illumination source and degrees of freedom of mask. Various algorithms for SMO are known. Typically, SMO algorithms receive as input a target pattern and initial guesses for the configuration of the illumination source and for the mask. The source variables and the mask variables are then simultaneously adjusted, such that a derived expected projected pattern is optimised. To derive an expected projected pattern, the SMO algorithms may also exploit further information, for example of the optical properties of the lithographic apparatus and physical and chemical reactions in the resist. As output, the optimised source and mask variables are provided as well as the expected projected pattern. Example SMO algorithms described in Stephen Hsu, et al., An Innovative Source-Mask co-Optimization (SMO) Method for Extending Low k1 Imaging, SPIE Asia, Vol. 7104 2008, and Stephen Hsu, et. al., Source-mask co-optimization: optimize design for imaging and impact of source complexity on lithography performance, Proc. SPIE 7520, 75200D (2009).

“Source only optimization” refers to computational methods which optimize the image fidelity of the projected pattern by illumination optimization. It has been shown that source only optimization is an effective method to improve lithography imaging performance by modulating the intensity distribution of the light source. Source only optimization algorithms often receive as input a target pattern, the mask and an initial guess for the configuration of the illumination source. The source variables are then adjusted, such that a derived expected projected pattern is optimised. In contrast to SMO, the mask is not optimised in source only optimization. As output, the optimised source variables are provided as well as the expected projected pattern. Source only optimization may be preferred over SMO in cases where is it no longer convenient to adjust the mask, for example because the mask has already been produced. An example source only optimization algorithm is described in Xu Ma et al, Optimization of lithography source illumination arrays using diffraction subspaces, Optics Express Vol. 26, Issue 4, pp. 3738-3755 (2018).

In an embodiment, the profile information is generated by a source mask optimization based on the patterning device MA.

In another embodiment the profile information is generated by a source only optimization based on the patterning device MA.

Regardless whether SMO or source only optimization is used to generate the profile information or whether a user, knowing the patterning device MA, selects profile information from a plurality of predetermined set of profile information, the generated or selected profile information depends on the properties of the patterning device MA, such as its symmetry. Therefore, properties of the patterning device MA, such as symmetries, are encoded in the profile information. As discussed below, in the embodiment the patterning information is used, typically without using information about the patterning device MA, to control the operation of the lithographic apparatus LA.

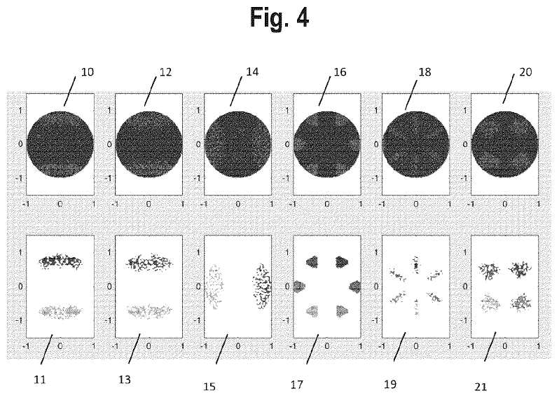

FIG. 4 shows in the top row (panels 10-20) example profile information obtained by source only optimization for six different patterning devices MA.

In this example, the beam-shaping device comprises a programmable mirror array, and the profile information includes a two-dimensional data array specifying a configuration of the programmable mirror array. Each element of the two-dimensional data array specifies whether a corresponding mirror is to be arranged in the on-state or off-state.

In the panels 10-20 of the top row, mirrors in the on-state are depicted in white and mirrors in the off-state are depicted in black. Panels 11, 13, 17, 19, and 21 of the lower row show results of a cluster algorithm applied to the arrays shown in the corresponding top panels, as described in detail below.

Panel 10 of FIG. 4 shows the optimised configuration of the programmable mirror array (illumination pupil) for a horizontal line pattern that has a pitch of 28 nm

Panel 12 of FIG. 4 shows the optimised configuration of the programmable mirror array for a horizontal line pattern that has a pitch of 30 nm.

Panel 14 of FIG. 4 shows the optimised configuration of the programmable mirror array for a vertical line pattern that has a pitch of 30 nm.

Panel 16 of FIG. 4 shows the optimised configuration of the programmable mirror array for a hole pattern arranged on a hexagonal lattice that has a pitch of 37 nm.

Panel 18 of FIG. 4 shows the optimised configuration of the programmable mirror array for a hole pattern arranged on a hexagonal lattice that has a pitch of 43 nm.

Panel 20 of FIG. 4 shows the optimised configuration of the programmable mirror array for a hole pattern arranged on a square lattice has a pitch of 40 nm.

Notably, the optimised configurations of the programmable mirror array are all distinctly different from each other. This demonstrates that properties of the patterning device MA are encoded in the optimised configuration of the programmable mirror array.

As noted above, by controlling the temperature of each region of each mirror of the projection system PS, any aberration of the mirrors due to the reflected electromagnetic radiation can be compensated for. In principle, other methods may be used to reduce or compensate for thermal aberrations, such as making micro adjustments to the control data for the programmable mirror array(s). To accurately predict the control actions, such as applying heating or cooling to specific regions of a mirror in the projection system PS, that compensate the induced heating by the electromagnetic radiation, the spatial distribution of the radiation on the mirror surface is taken into account. This is because the spatial distribution of the electromagnetic radiation on the mirror surface corresponds to the spatial distribution of the heat load experienced by the mirror.

If the spatial distribution of the radiation on the mirror surface is known, a mathematical model can be used to first predict wave front errors caused by the thermal aberrations and then derive control actions to reduce the wave front errors. To predict the wave front errors accurately, the model considers the underlying physics of each component of the lithographic apparatus.

The spatial distribution of electromagnetic radiation on mirrors in the projection system PS depends on the diffraction pattern of the patterning device MA produced under illumination by radiation beam B. Conventionally, knowledge of the patterning device MA is needed to derive the corresponding diffraction pattern, and to derive appropriate control actions using the aforementioned mathematical model. Details of the patterning device MA—and the corresponding diffraction pattern—are, however, often proprietary to the user of the lithographic apparatus and may not be available to a control apparatus that generates control actions for controlling the lithographic apparatus.

It is therefore desirable to provide improved control systems which are capable of compensating thermal aberration without requiring detailed knowledge of the patterning device MA.

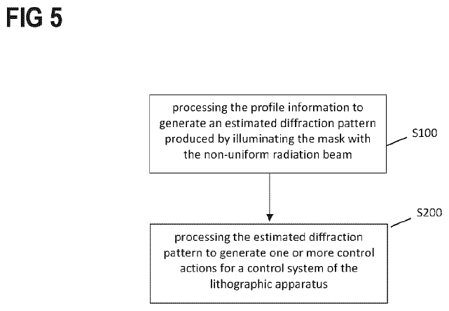

FIG. 5 shows a flow diagram of a method of generating one or more control actions for controlling a lithographic apparatus.

In general terms, the method generates control actions to compensate thermal aberrations without requiring detailed knowledge of the patterning device MA. To this end, the method first generates an estimation of the patterning device MA. This is possible because, as mentioned above, properties of the patterning device MA are encoded in the profile information. The estimated patterning device MA is then used to predict a diffraction pattern that is produced when the non-uniform radiation beam B illuminates the estimated patterning device MA.

The diffraction pattern of the estimated patterning device MA is then used to predict the wave front errors induced by this diffraction pattern on the mirror surface, and to generate appropriate control actions. Notably, the estimated patterning device MA may not be identical to the patterning device MA, because the profile information may not encode the details of the patterning device MA to a sufficiently high degree. However, the estimated patterning device MA does not need to be identical to the patterning device MA to enable generating effective control actions for controlling the lithographic apparatus. This is because minor details of the patterning device MA have little effect on the resulting heat load on the mirrors in the projection system PS.

In step S100 of the method, a control apparatus for the lithographic apparatus (such as a computer (e.g. microprocessor) provided in the lithographic apparatus, or a separate computer, such as a server system) processes the profile information to generate an estimated diffraction pattern produced by illuminating the mask with the non-uniform radiation beam.

In step S200 of the method, the control apparatus for the lithographic apparatus processes the estimated diffraction pattern to generate one or more control actions for a control system of the lithographic apparatus.

In an embodiment, to generate one or more control actions for a control system of the lithographic apparatus, a mathematical model is used to first predict wave front errors caused by the thermal heat load associated with the estimated diffraction pattern and then derive control actions to reduce the wave front errors. To predict the wave front errors accurately, the model may consider the underlying physics of each component of the lithographic apparatus. For example, such a physical mirror heating model is described in detail in WO 2022/012844 A1.

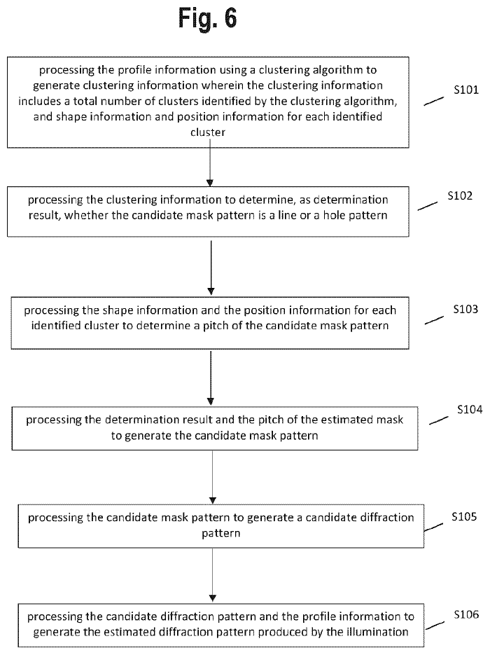

FIG. 6 shows a flow diagram of a method for performing step S100 of the method shown in FIG. 5.

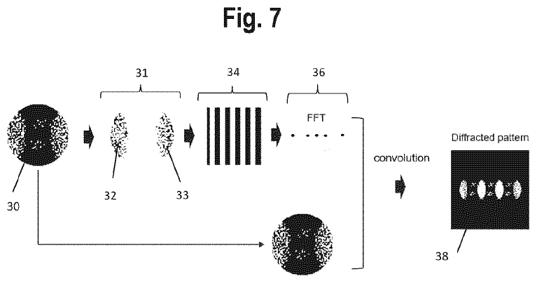

FIG. 7 is a schematic illustration of an example of the method of FIG. 6.

Referring to FIGS. 6 and 7, in step S101 of the method, the profile information is processed using a clustering algorithm to generate clustering information. The clustering information may include a total number of clusters identified by the clustering algorithm, and shape information and position information for each identified cluster.

In an embodiment, the cluster algorithm is a computational method that receives as input a data array comprised in the profile information, and performs a task of grouping elements of the input data array in such a way that elements in the same group (referred to as a cluster) are more similar to each other than to those in other groups. In an example, the cluster algorithm performs the grouping based on a distance between the elements.

In an embodiment, the cluster algorithm, after performing the grouping, derives a total number of clusters identified during the grouping. The cluster algorithm may further generate position information for each identified cluster, e.g. information specifying a center position of each identified cluster with the data array. The cluster algorithm may further generate shape information for each identified cluster, e.g. information specifying an outline of each identified cluster with the data array.

In an embodiment, the cluster algorithm provides as output clustering information including the total number of clusters identified by the clustering algorithm, and shape information and position information for each identified cluster.

In an embodiment, the cluster algorithm is density-based spatial clustering of applications with noise (DBSCAN). DBSCAN is described in detail in Ester, M. et al, “A density-based algorithm for discovering clusters in large spatial databases with noise”, in Proceedings of the Second International Conference on Knowledge Discovery in Databases and Data Mining, 226-231, Portland, OR; AAAI Press, 1996.

In broad terms, DBSCAN is an unsupervised clustering algorithm which can cluster elements of the two-dimensional array included in the profile information based on a predetermined neighbourhood search radius and a predetermined minimum number of elements for forming a cluster. Thus, DBSCAN can be used to reliably identify the main features of the two-dimensional array included in the profile information while filtering out scattered points of the two-dimensional array which do not contribute significantly to the heat load on the mirrors in the projection system PS. Further, DBSCAN does not require knowledge of the total number of expected clusters and is capable of identifying nested clusters. Those skilled in the art will appreciate that other cluster algorithms may be suitable if they have all or some of the above properties.

In an embodiment where the beam-shaping device comprises a programmable mirror array, and the profile information includes a two-dimensional data array specifying a configuration of the programmable mirror array, the clustering algorithm may process the two-dimensional data array. Similar to the two-dimensional arrays shown in the top row of FIG. 4, in the example of FIG. 7, each element of the example data array 30 specifies whether a corresponding mirror is in the on-state or off-state, with mirrors in the on-state depicted in white and mirrors in the off-state depicted in black.

Further referring to the example shown in FIG. 7, panel 31 illustrates a result of clustering algorithm DBSCAN applied to the example data array 30. The clustering algorithm identified two clusters 32, 33 of mirrors in the on-state.

Comparing example data array 30 and clustering result shown in panel 31, the clustering algorithm identifies the two major features of example data array 30 as two clusters. Notably, the clustering algorithm does not assign every on-state element of the example data array 30 to a cluster. In particular, the clustering algorithm does not assign on-state elements that are in low-density regions, i.e. on-state elements whose nearest neighbours are further away than a pre-determined distance, to any cluster. The contribution of these elements to the heat load experienced by the mirrors in the projection system PS is negligibly low. Not assigning the on-state elements in low-density regions is therefore beneficial because this simplifies the further processing of the clustering results without affecting the accuracy of the derived control actions.

Referring to FIG. 4, panels 11, 13, 17, 19, and 21 show results of DBSCAN applied to the arrays shown in the corresponding top panels. Similar to the example shown in FIG. 7, the clustering results in FIG. 4 show reliable grouping of the elements in the main features while not assigning elements in low density regions.

Referring back to FIG. 6, in step S102 of the method, the control apparatus for the lithographic apparatus processes the clustering information to determine, as a determination result, whether the candidate mask pattern is a line or a hole pattern.

In an embodiment, determining whether the candidate mask pattern is a line or a hole pattern is based on a symmetry of the identified clusters. For example, if the center positions of the clusters lie substantially on a straight line, the candidate mask pattern is determined to be a line pattern. This is, for example, the case when only two clusters are identified, as in the example shown in FIG. 7, and in clustering results 11, 13, and 15 shown in FIG. 4. In another example, if more than two clusters are identified and the center positions of the clusters form a pattern exhibiting a rotational symmetry, the candidate mask pattern is determined to be a hole pattern. This is the case, for example, in clustering results 17, 19, and 21 shown in FIG. 4.

In step S103 of the method, the control apparatus for the lithographic apparatus processes the shape information and the position information for each identified cluster to determine a pitch of the candidate mask pattern.

In an embodiment, the pitch is determined based on the distance between the center positions of the identified clusters. If the number of clusters is small (e.g. just two) the direction between their centers may be determined (normally, either horizontal or vertical) and a shift applied to one cluster in that direction until the overlap of the two clusters is maximized. The amount of the shift gives the pitch.

More generally (e.g. if the number of clusters is greater than two), to determine the pitch, each identified cluster may be processed by applying a horizontal or vertical shift to its elements until an overlap of these two clusters is maximized. In this way overlaps between all pairs of the identified clusters are found. Then the pitch p is derived from the vertical or horizontal distance d of the pair of clusters with the highest overlap,

$$p = \frac{λ}{( d * NA )}$$

where λ is the wavelength of the electromagnetic radiation and NA is the numerical aperture of the projection optics in the lithographic apparatus. In an example, the numerical value of the NA may be 0.13.

In the example of FIG. 7, the first cluster 32 can be shifted to overlap with the second cluster 33 by applying a horizontal shift.

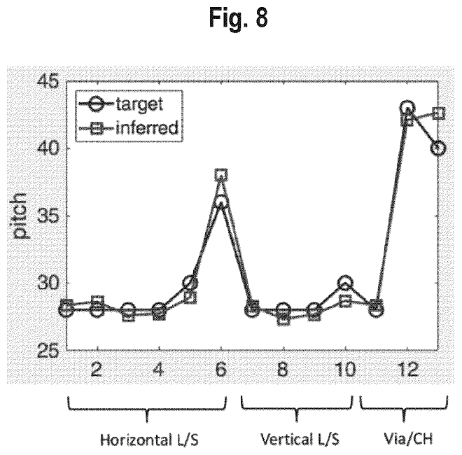

FIG. 8 shows pitches determined by performing S103 on 13 different patterning devices with the corresponding target values, numbered 1 to 13 with the respective numbers being the horizontal axis of FIG. 8. The first to sixth patterning devices have a horizontal line space pattern, the seventh to tenth patterning devices have a vertical line/space pattern, and the eleventh to thirteenth patterning devices use a via/contact hole pattern. FIG. 8 shows that the estimated pitches are close to the target values.

Referring back to FIG. 6, in step S104 of the method, the control apparatus for the lithographic apparatus processes the determination result and the pitch of the estimated mask to generate the candidate mask pattern.

The generated candidate mask pattern may be a two-dimensional array representing a line or hole pattern according to the determination result with the pitch p. The generated candidate mask pattern may be a binary array. In principle, the actual mask normally are binary, with patterns of lines/spaces or arrays of holes, and although other features may sometimes be present, there is in general one feature which dominates the diffraction pattern and which has a pitch which can be evaluated by the present method.

In the example of FIG. 7, the generated candidate mask pattern 34 is a line pattern. A spatial Fourier transform 36 of this is obtained, e.g. using a Fast Fourier Transform (FFT) algorithm.

In step S105 of the method, the control apparatus for the lithographic apparatus processes the candidate mask pattern to generate a candidate diffraction pattern (e.g. shown as candidate diffraction pattern 36 in FIG. 7).

In an embodiment, the candidate diffraction pattern is generated based on applying a Fourier transformation to the candidate mask pattern.

In the example of FIG. 7, the generated candidate diffraction pattern 36 is generated by applying a Fourier transformation to the candidate mask pattern 34.

In step S106 of the method, the control apparatus for the lithographic apparatus processes processing the candidate diffraction pattern and the profile information to generate the estimated diffraction pattern produced by the illumination system.

In an embodiment, the control apparatus for the lithographic apparatus processes the candidate diffraction pattern and the profile information to generate the estimated diffraction pattern produced by the lithographic apparatus.

In the example of FIG. 7, the estimated diffraction pattern 38 is generated by performing a convolution of the candidate diffraction pattern 36 and the profile information 30. This can be done, for example, by a multiplication of a spatial Fourier transform of the candidate diffraction pattern 36 (which is the candidate mask pattern 34) with a spatial Fourier transform of the data array 30, followed by an inverse Fourier transform back into the spatial domain.

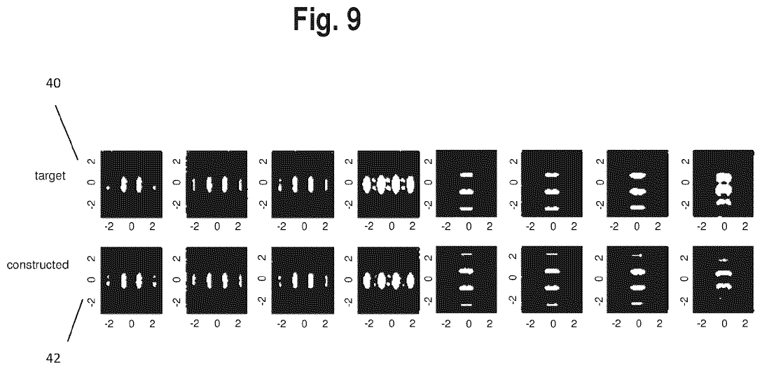

FIG. 9 shows in the lower panels 42 the estimated diffraction pattern generated by performing the method of FIG. 6 for eight different examples of profile information corresponding to eight different line/space patterning devices. The top panels 40 of FIG. 9 show corresponding diffraction pattern generated by optical simulation software taking into account the shape of the non-uniform radiation B and the patterning devices. FIG. 9 shows good agreement between the estimated and simulated diffraction patterns.

Although specific reference may be made in this text to the use of lithographic apparatus in the manufacture of ICs, it should be understood that the lithographic apparatus described herein may have other applications. Possible other applications include the manufacture of integrated optical systems, guidance and detection patterns for magnetic domain memories, flat-panel displays, liquid-crystal displays (LCDs), thin-film magnetic heads, etc.

Although specific reference may be made in this text to embodiments of the invention in the context of a lithographic apparatus, embodiments of the invention may be used in other apparatus. Embodiments of the invention may form part of a mask inspection apparatus, a metrology apparatus, or any apparatus that measures or processes an object such as a wafer (or other substrate) or mask (or other patterning device). These apparatus may be generally referred to as lithographic tools. Such a lithographic tool may use vacuum conditions or ambient (non-vacuum) conditions.

Although specific reference may have been made above to the use of embodiments of the invention in the context of optical lithography, it will be appreciated that the invention, where the context allows, is not limited to optical lithography and may be used in other applications, for example imprint lithography.

While specific embodiments of the invention have been described above, it will be appreciated that the invention may be practiced otherwise than as described. The descriptions above are intended to be illustrative, not limiting. Thus it will be apparent to one skilled in the art that modifications may be made to the invention as described without departing from the scope of the claims set out below.

Further embodiments are disclosed in the subsequent list of numbered clauses:

1. A computer-implemented method of generating one or more control actions for controlling a lithographic apparatus,
the lithographic apparatus comprising an illumination system for illuminating a mask with a non-uniform radiation beam,
the illumination system configured to receive from a radiation source a radiation beam, and comprising a beam-shaping device configured to receive data specifying profile information, and shape a profile of the radiation beam based on the profile information to form the non-uniform radiation beam;
the method comprising:
processing the profile information to generate an estimated diffraction pattern produced by illuminating the mask with the non-uniform radiation beam, and
processing the estimated diffraction pattern to generate one or more control actions for a control system of the lithographic apparatus.

2. The computer-implemented method according to clause 1 the profile information was generated by a source mask optimization or source only optimization based on a mask pattern.

3. The computer-implemented method according to clause 1 or 2 wherein processing the profile information to generate an estimated diffraction pattern produced by the illumination system comprises:
processing the profile information to generate a candidate mask pattern;
processing the candidate mask pattern to generate a candidate diffraction pattern, and
processing the candidate diffraction pattern and the profile information to generate the estimated diffraction pattern produced by the illumination system.

4. The computer-implemented method according to clause 3, wherein processing the profile information to generate a candidate mask pattern comprises:
processing the profile information using a clustering algorithm to generate clustering information, and
processing the clustering information to generate the candidate mask pattern,
   wherein the clustering information includes a total number of clusters identified by the clustering algorithm, and shape information and position information for each identified cluster.

5. The computer-implemented method according to clause 4, wherein processing the clustering information to generate the candidate mask pattern comprises:
processing the clustering information to determine, as a determination result, whether the candidate mask pattern is a line pattern or a hole pattern,
   processing the shape information and the position information for each identified cluster to determine a pitch of the candidate mask pattern, and
   processing the determination result and the pitch of the estimated mask to generate the candidate mask pattern.

6. The computer-implemented method according to any of clauses 3-5, wherein processing the candidate diffraction pattern and the profile information to generate the estimated diffraction pattern produced by the illumination system comprises performing a convolution of the candidate diffraction pattern and the profile information to generate the estimated diffraction pattern.

7. The computer-implemented method according to any preceding clause, wherein the beam-shaping device comprises a programmable mirror array.

8. The computer-implemented method according to clause 7, wherein the profile information is a two-dimensional array specifying a configuration of the programmable mirror array.

9 The computer-implemented method according to any preceding clause, wherein the control system is configured to apply a thermal conditioning process based on the control actions to at least part of the lithographic apparatus.

10. The computer-implemented method according to clause 9 in which the control system is configured to apply the thermal conditioning process to an optical element of the lithographic apparatus.

11. The computer-implemented method according to clause 10, wherein the optical element includes an optical surface including a plurality of regions, and the one or more control actions control the control system to apply a respective selected thermal conditioning process to each of the regions of the optical surface.

12. The computer-implemented method according to clause 11, wherein the optical element is a mirror or a lens.

13. The computer-implemented method according to clause 11, wherein the steps of processing the profile information, and processing the estimated diffraction pattern are performed by a processor of the lithographic apparatus.

14. A computer system comprising a processor and a data storage device, the data storage device storing program instructions which, when executed by the processor, cause the processor to carry out the method of any preceding clause.

15. A computer program product comprising instructions which, when executed by a computer, cause the computer to carry out the method of any of clauses 1 to 12.

16. A control apparatus for a lithographic apparatus comprising an illumination system for illuminating a mask with a non-uniform radiation beam, the illumination system configured to receive from a radiation source a radiation beam, and comprising a beam-shaping device configured to receive data specifying profile information, and shape a profile of the radiation beam based on the profile information to form the non-uniform radiation beam;
the control apparatus being configured to:
process the profile information to generate an estimated diffraction pattern produced by illuminating the mask with the non-uniform radiation beam, and
process the estimated diffraction pattern to generate one or more control actions for a control system of the lithographic apparatus.

17. The control apparatus according to clause 15, the control apparatus being further configured to generate the profile information by a source mask optimization or source only optimization based on a mask pattern.

18. The control apparatus according to clause 16 or 17, the control apparatus being configured to process the profile information to generate an estimated diffraction pattern produced by the illumination system by:
processing the profile information to generate a candidate mask pattern;
processing the candidate mask pattern to generate a candidate diffraction pattern, and
processing the candidate diffraction pattern and the profile information to generate the estimated diffraction pattern produced by the illumination system.

19. The control apparatus according to clause 18, the control apparatus being configured to process the profile information to generate a candidate mask pattern by:
processing the profile information using a clustering algorithm to generate clustering information, and
processing the clustering information to generate the candidate mask pattern, wherein the clustering information includes a total number of clusters identified by the clustering algorithm, and shape information and position information for each identified cluster.

20. The control apparatus to clause 19, the control apparatus being configured to process the clustering information to generate the candidate mask pattern by:
processing the clustering information to determine, as a determination result, whether the candidate mask pattern is a line pattern or a hole pattern,
   processing the shape information and the position information for each identified cluster to determine a pitch of the candidate mask pattern, and
   processing the determination result and pitch of the estimated mask to generate the candidate mask pattern.

21. The control apparatus according to any of clauses 18-20, the control apparatus being configured to process the candidate diffraction pattern and the profile information to generate the estimated diffraction pattern produced by the illumination system, by performing a convolution of the candidate diffraction pattern and the profile information to generate the estimated diffraction pattern.

22. A lithographic apparatus comprising a control apparatus according to any of clauses 16 to 21, and an illumination system for illuminating a mask with a non-uniform radiation beam, the illumination system configured to receive from a radiation source a radiation beam, and comprising a beam-shaping device configured to receive data specifying profile information, and to shape a transverse profile of the radiation beam based on the profile information to form the non-uniform radiation beam, the control apparatus being configured to supply the control actions to a control system of the lithographic apparatus.

23. The lithographic apparatus according to clause 22, wherein the beam-shaping device comprises a programmable mirror array.

24. The lithographic apparatus according to clause 23, wherein the profile information is a two-dimensional array representing a configuration of the programmable mirror array.

25. The lithographic apparatus according to clause 23 or clause 24, wherein the control system is configured to apply a thermal conditioning process based on the control actions to of at least part of the lithographic apparatus.

26. The lithographic apparatus according to clause 25 in which the control system is configured to apply the thermal conditioning process to an optical element of the lithographic apparatus.

27. The lithographic apparatus according to clause 26, wherein the optical element includes an optical surface including a plurality of regions, and the one or more control actions comprise applying a different thermal conditioning process to each of the regions of the optical surface.

28. The lithographic apparatus according to clause 26 or 27, wherein the optical element is a mirror or a lens.

1. A method of generating one or more control actions for controlling a lithographic apparatus, the lithographic apparatus comprising an illumination system for illuminating a mask with a non-uniform radiation beam, the illumination system configured to receive, from a radiation source, a radiation beam, and comprising a beam-shaping device configured to receive data specifying profile information, and shape a profile of the radiation beam based on the profile information to form the non-uniform radiation beam, the method comprising:
processing, by a hardware computer system, the profile information to generate an estimated diffraction pattern produced by illuminating the mask with the non-uniform radiation beam, and
processing the estimated diffraction pattern to generate one or more control actions for a control system of the lithographic apparatus.

2. The method according to claim 1, wherein the profile information is generated by a source mask optimization or source only optimization based on a mask pattern.

3. The method according to claim 1, wherein processing the profile information comprises:
processing the profile information to generate a candidate mask pattern;
processing the candidate mask pattern to generate a candidate diffraction pattern; and
processing the candidate diffraction pattern and the profile information to generate the estimated diffraction pattern produced by the illumination system.

4. The method according to claim 3, wherein processing the profile information to generate a candidate mask pattern comprises:
processing the profile information using a clustering algorithm to generate clustering information, and
processing the clustering information to generate the candidate mask pattern,
wherein the clustering information includes a total number of clusters identified by the clustering algorithm, and shape information and position information for each identified cluster.

5. The method according to claim 4, wherein processing the clustering information to generate the candidate mask pattern comprises:
processing the clustering information to determine, as a determination result, whether the candidate mask pattern is a line pattern or a hole pattern,
processing the shape information and the position information for each identified cluster to determine a pitch of the candidate mask pattern, and
processing the determination result and the pitch of the estimated mask to generate the candidate mask pattern.

6. The method according to claim 3, wherein processing the candidate diffraction pattern and the profile information to generate the estimated diffraction pattern produced by the illumination system comprises performing a convolution of the candidate diffraction pattern and the profile information to generate the estimated diffraction pattern.

7. The method according to claim 1, wherein the beam-shaping device comprises a programmable mirror array.

8. The method according to claim 7, wherein the profile information is a two-dimensional array specifying a configuration of the programmable mirror array.

9. The method according to claim 1, wherein the control system is configured to apply a thermal conditioning process based on the one or more control actions to at least part of the lithographic apparatus.

10. The method according to claim 9 wherein the control system is configured to apply the thermal conditioning process to an optical element of the lithographic apparatus.

11. The method according to claim 10, wherein the optical element includes an optical surface including a plurality of regions, and the one or more control actions control the control system to apply a respective selected thermal conditioning process to each of the regions of the optical surface.

12. The method according to claim 11, wherein the optical element is a mirror or a lens.

13. The method according to claim 11, wherein the processing the profile information, and processing the estimated diffraction pattern are performed by a processor of the lithographic apparatus.

14. A computer system comprising one or more processors and a data storage device, the data storage device storing program instructions which, when executed by the one or more processors, cause the one or more processors to carry out at least the method of claim 1.

15. A non-transitory computer program product comprising instructions which, when executed by a computer system, cause the computer system to carry out at least the method of claim 1.

16. A control apparatus for a lithographic apparatus comprising an illumination system for illuminating a mask with a non-uniform radiation beam, the illumination system configured to receive, from a radiation source, a radiation beam, and comprising a beam-shaping device configured to receive data specifying profile information, and shape a profile of the radiation beam based on the profile information to form the non-uniform radiation beam, the control apparatus being configured to:
process the profile information to generate an estimated diffraction pattern produced by illuminating the mask with the non-uniform radiation beam, and
process the estimated diffraction pattern to generate one or more control actions for a control system of the lithographic apparatus.

17. A lithographic apparatus comprising:
the control apparatus according to claim 16, and
an illumination system for illuminating a mask with a non-uniform radiation beam, the illumination system configured to receive, from a radiation source, a radiation beam, and comprising a beam-shaping device configured to receive data specifying profile information, and shape a profile of the radiation beam based on the profile information to form the non-uniform radiation beam,
wherein the control apparatus is configured to supply the one or more control actions to a control system of the lithographic apparatus.

18. The control apparatus of claim 16, wherein the profile information is generated by a source mask optimization or source only optimization based on a mask pattern.

19. The control apparatus of claim 16, further configured to:
process the profile information to generate a candidate mask pattern;
process the candidate mask pattern to generate a candidate diffraction pattern; and
process the candidate diffraction pattern and the profile information to generate the estimated diffraction pattern produced by the illumination system.

20. The control apparatus of claim 16, further configured to apply a thermal conditioning process based on the one or more control actions to at least part of the lithographic apparatus.
